(19) United States
(12) Patent Application Publication
(10) Pub. No.: US 2026/0149436 A1
(43) Pub. Date: May 28, 2026

(54) PULSE LASER POWER SOURCE, PULSE LASER DEVICE, AND ELECTRONIC DEVICE MANUFACTURING METHOD

(71) Applicant: Gigaphoton Inc., Oyama-shi (JP)

(72) Inventor: Takeshi UEYAMA, Oyama-shi (JP)

(73) Assignee: Gigaphoton Inc., Oyama-shi (JP)

(21) Appl. No.: 19/348,385

(22) Filed: Oct. 2, 2025

(30) Foreign Application Priority Data
Nov. 26, 2024 (JP) 2024-205832

(51) Int. Cl. H03K 3/57; H01S 3/097; H01S 3/0975

(52) U.S. Cl. CPC H03K 3/57; H01S 3/09702; H01S 3/0975

(57) ABSTRACT

A pulse laser power source includes a step-up transformer in which a pulse current flows to a primary side, a first magnetic pulse compression circuit transferring charge of the first transfer capacitor to a second transfer capacitor, a second magnetic pulse compression circuit transferring charge of the second transfer capacitor to a peaking capacitor, a reset circuit including reset windings performing magnetic reset, and a series circuit of a resistor and an inductor connected in parallel to the peaking capacitor. A resistance value of the resistor is in a range of 100 to 1000Ω inclusive. An inductance L of the inductor satisfies ((ωL)²+R²)^{1/2}>1/ωCp and L≤(1/Rep−Tm)×R/2, where a capacitance of the peaking capacitor is Cp, a resonance angular frequency during transfer of charge from the second transfer capacitor to the peaking capacitor is ω, a repetition frequency is Rep, and a required time for the magnetic reset is Tm.

### CROSS-REFERENCE TO RELATED APPLICATIONS

The present application claims the benefit of Japanese Patent Application No. 2024-205832, filed on Nov. 26, 2024, the entire contents of which are hereby incorporated by reference.

### BACKGROUND

### 1. Technical Field

The present disclosure relates to a pulse laser power source, a pulse laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. A gas laser device with a line-narrowed spectral line width is referred to as a line narrowing gas laser device.

### LIST OF DOCUMENTS

### Patent Documents

Patent Document 1: Japanese Patent Application Publication No. 2010-073948

### SUMMARY

A pulse laser power source according to an aspect of the present disclosure includes a step-up transformer in which a pulse current from a main capacitor flows to a primary side; a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor; a second magnetic pulse compression circuit including the second transfer capacitor and a second magnetic switch connected to the second transfer capacitor, and configured to transfer charge of the second transfer capacitor to a peaking capacitor; a reset circuit including reset windings that reversely excite cores of the step-up transformer, the first magnetic switch, and the second magnetic switch to perform magnetic reset; and a series circuit of a resistor and an inductor connected in parallel to the peaking capacitor. Here, a resistance value of the resistor is equal to or more than 100Ω and equal to or less than 1000Ω. An inductance L of the inductor satisfies two expressions of ((ωL)²+R²)^{1/2}>1/ωCp and L≤(1/Rep−Tm)×R/2, where a capacitance of the peaking capacitor is Cp, a resonance angular frequency during transfer of charge from the second transfer capacitor to the peaking capacitor is ω, a repetition frequency is Rep, and a required time for the magnetic reset is Tm.

A pulse laser device according to an aspect of the present disclosure includes a step-up transformer in which a pulse current from a main capacitor flows to a primary side; a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor; a second magnetic pulse compression circuit including the second transfer capacitor and a second magnetic switch connected to the second transfer capacitor, and configured to transfer charge of the second transfer capacitor to a peaking capacitor; a reset circuit including reset windings that reversely excite cores of the step-up transformer, the first magnetic switch, and the second magnetic switch to perform magnetic reset; a series circuit of a resistor and an inductor connected in parallel to the peaking capacitor; and a laser chamber including a pair of electrodes arranged therein and connected to the peaking capacitor. Here, a resistance value of the resistor is equal to or more than 100Ω and equal to or less than 1000Ω. An inductance L of the inductor satisfies two expressions of ((ωL)²+R²)^{1/2}>1/ωCp and L≤(1/Rep−Tm)×R/2, where a capacitance of the peaking capacitor is Cp, a resonance angular frequency during transfer of charge from the second transfer capacitor to the peaking capacitor is ω, a repetition frequency is Rep, and a required time for the magnetic reset is Tm.

An electronic device manufacturing method according to an aspect of the present disclosure includes generating pulse laser light using a pulse laser device, outputting the pulse laser light to an exposure apparatus, and exposing a photosensitive substrate to the pulse laser light in the exposure apparatus to manufacture an electronic device. Here, the pulse laser device includes a step-up transformer in which a pulse current from a main capacitor flows to a primary side; a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor; a second magnetic pulse compression circuit including the second transfer capacitor and a second magnetic switch connected to the second transfer capacitor, and configured to transfer charge of the second transfer capacitor to a peaking capacitor; a reset circuit including reset windings that reversely excite cores of the step-up transformer, the first magnetic switch, and the second magnetic switch to perform magnetic reset; a series circuit of a resistor and an inductor connected in parallel to the peaking capacitor; and a laser chamber including a pair of electrodes arranged therein and connected to the peaking capacitor. A resistance value of the resistor is equal to or more than 100Ω and equal to or less than 1000Ω. An inductance L of the inductor satisfies two expressions of ((ωL)²+R²)^{1/2}>1/ωCp and L≤(1/Rep−Tm)×R/2, where a capacitance of the peaking capacitor is Cp, a resonance angular frequency during transfer of charge from the second transfer capacitor to the peaking capacitor is ω, a repetition frequency is Rep, and a required time for the magnetic reset is Tm.

### BRIEF DESCRIPTION OF THE DRAWINGS

Embodiments of the present disclosure will be described below merely as examples with reference to the accompanying drawings.

FIG. 1 shows the configuration of an exposure system of a comparative example.

FIG. 2 shows the configuration of a pulse laser device shown in FIG. 1.

FIG. 3 shows the configuration of a pulse power module shown in FIG. 2.

FIG. 4 is a graph showing a change in a voltage applied between electrodes inside a laser chamber in the comparative example.

FIG. 5 shows the configuration of the pulse laser device of a first embodiment.

FIG. 6 shows the configuration of the pulse power module of the first embodiment.

FIG. 7 is a graph showing a change in the voltage applied between the electrodes inside the laser chamber in the first embodiment.

FIG. 8 shows the configuration of the pulse laser device of a second embodiment.

### DESCRIPTION OF EMBODIMENTS

### Contents

1. Comparative example
   1.1 Exposure system
   1.2 Exposure apparatus 200
   1.3 Pulse laser device 100
      1.3.1 Configuration
      1.3.2 Operation
   1.4 Pulse power module 13
      1.4.1 Configuration
      1.4.2 Operation
2. Problem of comparative example
3. Pulse power module 13a including resistor R1 and inductor L1
   3.1 Configuration
   3.2 Operation
   3.3 Parameter
   3.4 Effect
4. Pulse laser device 100b including amplifier 120
   4.1 Configuration
   4.2 Operation
   4.3 Effect
5. Others
   5.1 Processor 130
   5.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Exposure System

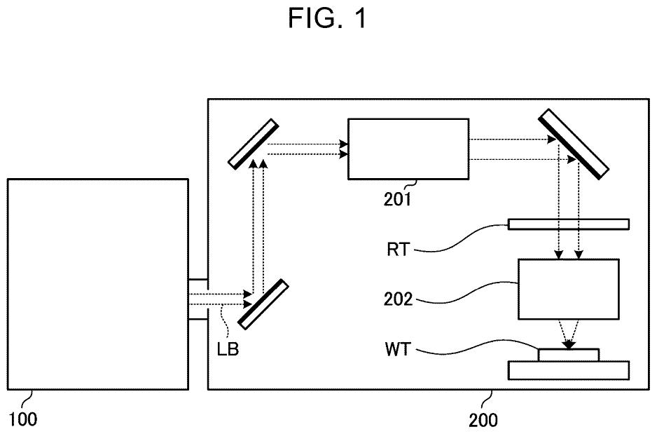

FIG. 1 shows the configuration of an exposure system in a comparative example. The comparative example of the present disclosure is an example recognized by the applicant as known only by the applicant, and is not a publicly known example admitted by the applicant.

The exposure system includes a pulse laser device 100 and an exposure apparatus 200. In FIG. 1, the pulse laser device 100 is shown in a simplified manner. The pulse laser device 100 is configured to output pulse laser light LB toward the exposure apparatus 200.

### 1.2 Exposure Apparatus 200

As shown in FIG. 1, the exposure apparatus 200 includes an illumination optical system 201 and a projection optical system 210. The illumination optical system 201 illuminates a reticle pattern of a reticle (not shown) arranged on a reticle stage RT with the pulse laser light LB incident from the pulse laser device 100. The projection optical system 202 causes the pulse laser light LB transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light LB reflecting the reticle pattern. After the reticle pattern is transferred onto the semiconductor wafer by the exposure process described above, an electronic device can be manufactured through a plurality of processes.

### 1.3 Pulse Laser Device 100

### 1.3.1 Configuration

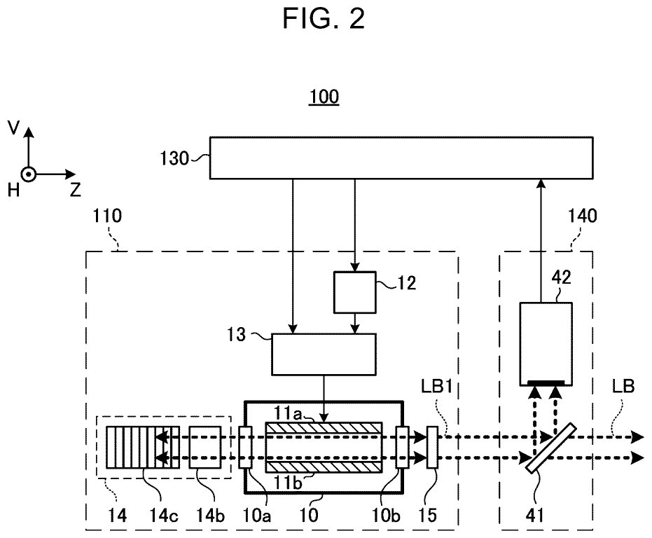

FIG. 2 shows the configuration of the pulse laser device 100 shown in FIG. 1. The pulse laser device 100 includes a laser oscillator 110, a processor 130, and a monitor module 140. The laser oscillator 110 includes a laser chamber 10, a charger 12, a pulse power module 13, a line narrowing module 14, and an output mirror 15. The output mirror 15 and a grating 14c included in the line narrowing module 14 configure an optical resonator. The configuration of the processor 130 will be described later.

The laser chamber 10 includes windows 10a, 10b, and is arranged such that the windows 10a, 10b are located on the optical path of the optical resonator. The laser chamber 10 is configured to accommodate a laser gas including components of a laser gain medium, and includes a pair of electrodes 11a, 11b that apply a voltage to the laser gain medium. The laser gain medium is, for example, ArF or KrF.

The travel direction of pulse laser light LB1 output from the output mirror 15 is represented by a Z direction. The direction in which the electrodes 11a, 11b face each other is represented as a V direction or a −V direction. The Z direction and the V direction are perpendicular to each other, and the direction perpendicular to both of them is represented by an H direction or a −H direction. In FIG. 2, the configuration of the pulse laser device 100 is shown as viewed in the −H direction.

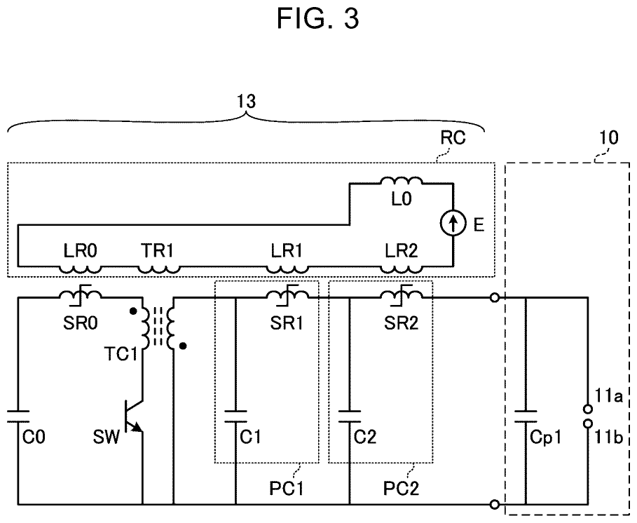

The pulse power module 13 includes a main capacitor C0 and a switch SW which will be described later with reference to FIG. 3. The main capacitor C0 is connected to the charger 12 and the switch SW is connected to the processor 130. Output terminals of the pulse power module 13 are connected to the electrodes 11a, 11b.

The line narrowing module 14 includes a prism 14b and the grating 14c. The prism 14b is arranged on the optical path of light output from the window 10a. The prism 14b is rotatable about an axis parallel to the V direction by a rotation stage (not shown). The grating 14c is arranged on the optical path of the light having transmitted through the prism 14b. The output mirror 15 is configured by a partial reflection mirror.

The monitor module 140 includes a beam splitter 41 and an optical sensor 42. The beam splitter 41 is arranged on the optical path of the pulse laser light LB1 output from the output mirror 15, and is configured to transmit a part of the pulse laser light LB1 at a high transmittance as the pulse laser light LB, and to reflect another part thereof. The optical sensor 42 is arranged on the optical path of the pulse laser light LB1 reflected by the beam splitter 41. The optical sensor 42 is configured to be capable of measuring a center wavelength and a pulse energy of the pulse laser light LB1.

### 1.3.2 Operation

The processor 130 receives data of a target value of the center wavelength, data of a target value of the pulse energy, and a trigger signal from the exposure apparatus 200. The processor 130 transmits an initial setting signal to the line narrowing module 14 based on the target value of the center wavelength. The processor 130 transmits an initial setting signal of a charge voltage to the charger 12 based on the target value of the pulse energy. Further, the processor 130 transmits an oscillation trigger signal to the switch SW of the pulse power module based on the trigger signal.

The charger 12 charges the main capacitor C0 based on the charge voltage set by the processor 130. When receiving the oscillation trigger signal from the processor 130, the switch SW is turned on. When the switch SW is turned on, the pulse power module 13 generates a pulse high voltage from the electric energy charged in the main capacitor C0, and applies the high voltage to the electrodes 11a, 11b.

When the high voltage is applied to the electrodes 11a, 11b, discharge occurs between the electrodes 11a, 11b. The laser gas in the laser chamber 10 is excited by the energy of the discharge, and shifts to a high energy level. When the excited laser gas then shifts to a low energy level, light having a wavelength corresponding to the difference between the energy levels is emitted.

The light generated in the laser chamber 10 is output to the outside of the laser chamber 10 through the windows 10a, 10b. The beam width of the light output from the window 10a is expanded by the prism 14b in a plane parallel to an HZ plane. The light transmitted through the prism 14b is incident on the grating 14c.

The light incident on the grating 14c is reflected by a plurality of grooves of the grating 14c and is diffracted in a direction corresponding to the wavelength of the light. By matching the incident angle of the light incident on the grating 14c with the diffraction angle of the diffracted light having a desired wavelength, the wavelength of the diffracted light returning to the prism 14b from the grating 14c is selected. In accordance with a change of posture due to the rotation angle of the rotation stage, the incident angle of the light incident on the grating 14c changes, and the wavelength selected by the line narrowing module 14 changes. The prism 14b reduces the beam width in the HZ plane of the diffracted light returning from the grating 14c and returns the light to the inside of the laser chamber 10 through the window 10a.

The output mirror 15 transmits and outputs a part of the light output from the window 10b, and reflects another part thereof back into the laser chamber 10.

In this way, the light output from the laser chamber 10 reciprocates between the line narrowing module 14 and the output mirror 15. The light is amplified every time it passes through a discharge space between the electrodes 11a, 11b, and is line-narrowed every time the light is turned back by the line narrowing module 14. Thus, the light having undergone laser oscillation and line narrowing is output from the output mirror 15 as pulse laser light LB1, and enters the exposure apparatus 200 as the pulse laser light LB.

The processor 130 receives the measurement value of the center wavelength from the monitor module 140, and performs feedback control of the line narrowing module 14 based on the target value of the center wavelength and the measurement value of the center wavelength. The processor 130 receives the measurement value of the pulse energy from the monitor module 140, and performs feedback control of the charge voltage of the charger 12 based on the target value of the pulse energy and the measurement value of the pulse energy.

### 1.4 Pulse Power Module 13

### 1.4.1 Configuration

FIG. 3 shows the configuration of the pulse power module 13 shown in FIG. 2. In addition to the main capacitor C0 and the switch SW, the pulse power module 13 includes a step-up transformer TC1, magnetic switches SR0, SR1, SR2, first and second transfer capacitors C1, C2, and a reset circuit RC. The magnetic switches SR1, SR2 correspond to the first and second magnetic switches in the present disclosure, respectively. The output terminals of the pulse power module 13 are connected to a peaking capacitor Cp1 and the electrodes 11a, 11b which are connected in parallel to each other. The peaking capacitor Cp1 and the electrodes 11a, 11b are included in the laser chamber 10.

Each of the magnetic switches SR0 to SR2 includes a saturable reactor. Each of the magnetic switches SR0 to SR2 is configured to switch into a low-impedance state when a time integration value of the voltage applied between both ends thereof reaches a predetermined value determined by characteristics of the each magnetic switch.

One terminal of the magnetic switch SR0 is connected to one terminal of the main capacitor C0. The other terminal of the main capacitor C0 is connected to the reference potential. The other terminal of the magnetic switch SR0 is connected to the reference potential via a primary winding of the step-up transformer TC1 and the switch SW which are connected in series with each other.

One terminal of the magnetic switch SR1 is connected to the reference potential via a secondary winding of the step-up transformer TC1 and is connected to one terminal of the first transfer capacitor C1. The other terminal of the first transfer capacitor C1 is connected to the reference potential. That is, the secondary winding of the step-up transformer TC1 and the first transfer capacitor C1 are connected in parallel to each other. The first transfer capacitor C1 and the magnetic switch SR1 configure a first magnetic pulse compression circuit PC1.

The other terminal of the magnetic switch SR1 is connected to one terminal of the magnetic switch SR2 and is connected to one terminal of the second transfer capacitor C2. The other terminal of the second transfer capacitor C2 is connected to the reference potential. The second transfer capacitor C2 and the magnetic switch SR2 configure a second magnetic pulse compression circuit PC2.

The other terminal of the magnetic switch SR2 is connected to one terminal of the peaking capacitor Cp1 and the electrode 11a. The other terminal of the peaking capacitor Cp1 and the electrode 11b are connected to the reference potential.

The reset circuit RC includes a DC power source E, and a reactor L0 and reset windings LR0, TR1, LR1, LR2 connected in series to the DC power source E. Cores of the reset windings LR0, LR1, LR2, TR1 are common to cores of the magnetic switches SR0, SR1, SR2 and the step-up transformer TC1, respectively.

### 1.4.2 Operation

The main capacitor C0 is charged by the charger 12. When the switch SW receives the oscillation trigger signal from the processor 130 and is turned on, the voltage of the main capacitor C0 is applied to the magnetic switch SR0. When the time integration value of the voltage applied to the magnetic switch SR0 becomes a predetermined value, the magnetic switch SR0 is turned on, and a pulse current flows from the main capacitor C0 through the magnetic switch SR0, the primary winding of the step-up transformer TC1, and the switch SW.

When the current flows through the primary winding of the step-up transformer TC1, a current corresponding to the winding ratio of the step-up transformer TC1 flows through the secondary winding of the step-up transformer TC1 due to electromagnetic induction. When a current flows through the secondary winding of the step-up transformer TC1, the first transfer capacitor C1 is charged and the voltage of the first transfer capacitor C1 is applied to the magnetic switch SR1. When the time integration value of the voltage applied to the magnetic switch SR1 becomes a predetermined value, the magnetic switch SR1 is turned on, and a pulse current flows through the magnetic switch SR1.

When the current flows through the magnetic switch SR1, charge of the first transfer capacitor C1 is transferred to the second transfer capacitor C2, so that the second transfer capacitor C2 is charged and the voltage of the second transfer capacitor C2 is applied to the magnetic switch SR2. The pulse width of the current at the time of charging the second transfer capacitor C2 is shorter than the pulse width of the current at the time of charging the first transfer capacitor C1, and the voltage is increased. When the time integration value of the voltage applied to the magnetic switch SR2 becomes a predetermined value, the magnetic switch SR2 is turned on, and a pulse current flows through the magnetic switch SR2.

When the current flows through the magnetic switch SR2, charge of the second transfer capacitor C2 is transferred to the peaking capacitor Cp1, and the peaking capacitor Cp1 is charged. The pulse width of the current at the time of charging the second transfer capacitor C2 is shorter than the pulse width of the current at the time of charging the peaking capacitor Cp1, and the voltage is increased.

When the voltage of the peaking capacitor Cp1 reaches a breakdown voltage of the laser gas, discharge occurs between the electrodes 11a, 11b. As a result, the laser gas is excited and laser oscillation occurs. When switching operation of the switch SW is performed at a predetermined repetition frequency, the pulse laser light LB is output at the repetition frequency.

After the peaking capacitor Cp1 is charged, magnetic reset is performed for the cores of the magnetic switches SR0 to SR2 and the step-up transformer TC1. To perform magnetic reset, in the reset circuit RC, the DC power source E causes a current to flow through the reset windings LR0, LR1, LR2, TR1, thereby causing reverse excitation. The direction of the current flowing through the windings of the magnetic switches SR0 to SR2 and the step-up transformer TC1 when the pulse is generated is opposite to the direction of the current flowing through the reset windings LR0, LR1, LR2, TR1 when magnetic reset is performed.

### 2. Problem of Comparative Example

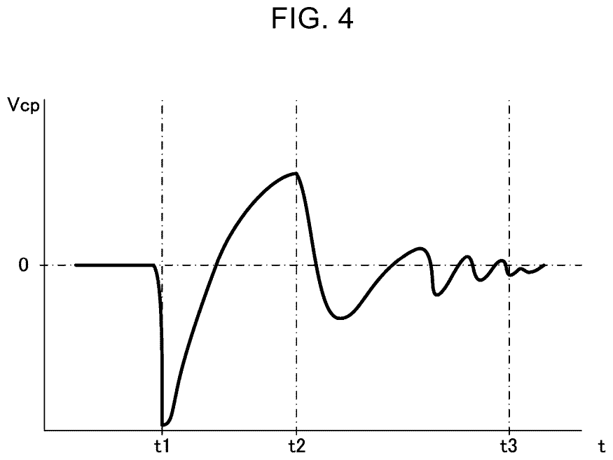

FIG. 4 is a graph showing a change in the voltage applied between the electrodes 11a, 11b inside the laser chamber 10 in the comparative example. The horizontal axis represents time t, and the vertical axis represents a voltage Vcp of the peaking capacitor Cp1. The voltage Vcp is equivalent to the voltage between the electrodes 11a, 11b.

At time t1, when a negative high voltage pulse is generated and discharge between the electrodes 11a, 11b starts, the voltage Vcp then reverses and rises. When magnetic reset for the cores of the magnetic switches SR0, SR1, SR2 and the step-up transformer TC1 is completed at time t2, the voltage Vcp is then attenuated while oscillating.

In order to improve semiconductor production efficiency of the exposure apparatus 200, it may be required to increase the repetition frequency of the pulse laser light LB. When the repetition frequency of the pulse laser light LB is, for example, 6 kHz, the period of discharge is 166.7 μs. However, when the repetition frequency of the pulse laser light LB is increased, the voltage Vcp may not be attenuated enough until the subsequent discharge. For example, if the subsequent discharge is performed at time t3 or earlier, the discharge voltage may vary, and the pulse energy of the pulse laser light LB may vary.

Embodiments described below relate to stabilizing the pulse energy of the pulse laser light LB by suppressing oscillation of the voltage Vcp after magnetic reset.

### 3. Pulse Power Module 13a Including Resistor R1 and Inductor L1

### 3.1 Configuration

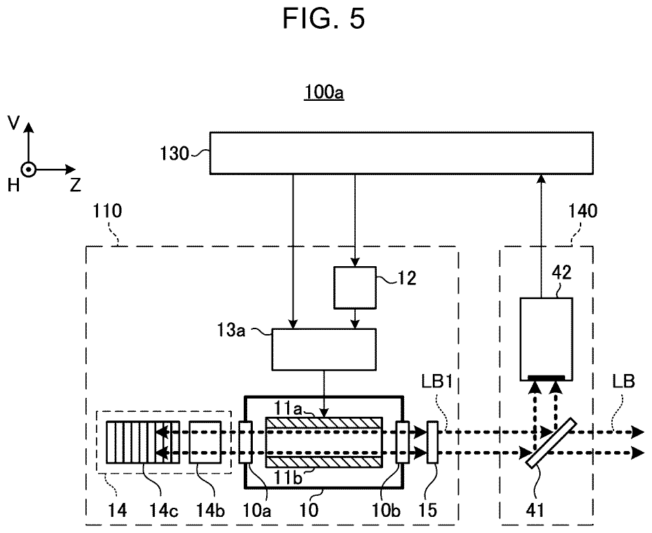

FIG. 5 shows the configuration of a pulse laser device 100a of a first embodiment. The pulse laser device 100a is different from the pulse laser device 100 of the comparative embodiment in that a pulse power module 13a is included instead of the pulse power module 13. The pulse power module 13a is an example of the pulse laser power source in the present disclosure.

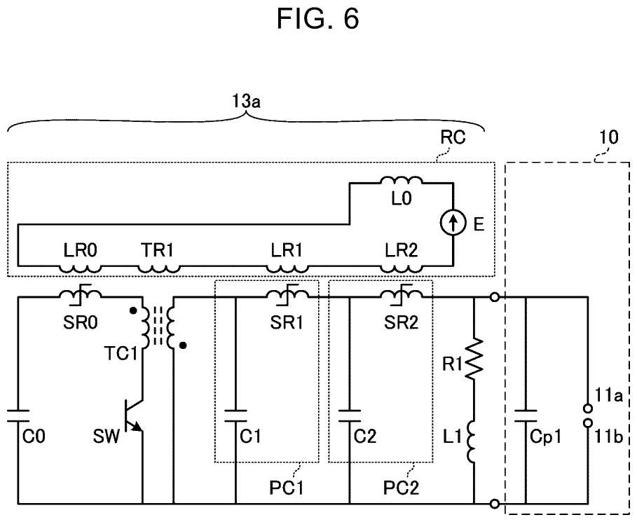

FIG. 6 shows the configuration of the pulse power module 13a of the first embodiment. In the pulse power module 13a, the other terminal of the magnetic switch SR2, that is, the terminal connected to the peaking capacitor Cp1 is connected to the reference potential via a series circuit of a resistor R1 and an inductor L1. That is, the series circuit of the resistor R1 and the inductor L1 is connected in parallel to the peaking capacitor Cp1.

### 3.2 Operation

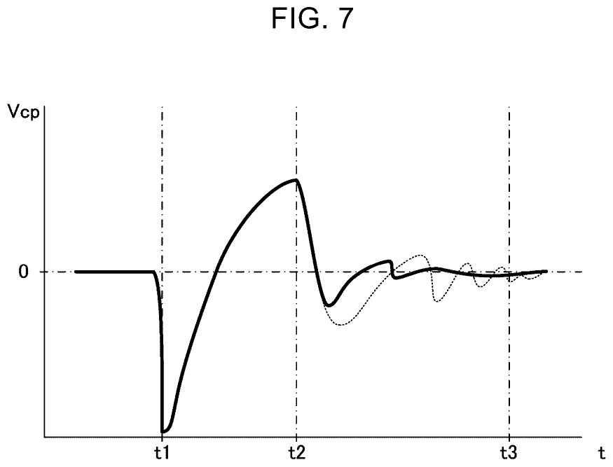

FIG. 7 is a graph showing a change in the voltage applied between the electrodes 11a, 11b inside the laser chamber 10 in the first embodiment. The horizontal axis represents time t, and the vertical axis represents the voltage Vcp of the peaking capacitor Cp1. The change in the voltage Vcp up to time t2 is similar to that in the comparative example.

At time t2, after magnetic reset of the cores of the magnetic switches SR0, SR1, SR2 and the step-up transformer TC1 is completed, the voltage Vcp attenuates while oscillating, but the oscillation of the voltage Vcp attenuates earlier than in the comparative example shown by a dashed line. This is because a current flows through the resistor R1 as the voltage Vcp oscillates and an energy is consumed.

If a large current flows through the resistor R1 when charge is transferred from the second transfer capacitor C2 to the peaking capacitor Cp1, the peaking capacitor Cp1 may be insufficiently charged. The transfer of charge from the second transfer capacitor C2 to the peaking capacitor Cp1 is hereinafter referred to as “main transfer”. By providing the inductor L1 having a sufficient inductance L, it is possible to suppress a large pulse current from flowing through the resistor R1 during main transfer.

### 3.3 Parameter

It is desirable that the oscillation of the voltage Vcp is sufficiently attenuated before the subsequent discharge. For example, it is desirable to set the amplitude of the oscillation to be equal to or less than 20 V before the subsequent discharge. In the configuration of the pulse power module 13a shown in FIG. 6, simulation was performed with the inductance L of the inductor L1 set to 0.1 mH while changing a resistance value R of the resistor R1, and the amplitude of the oscillation of the voltage Vcp at the time of the subsequent discharge was calculated. As a result, the resistance value R of the resistor R1 required for the amplitude at the time of the subsequent discharge to be equal to or less than 20 V value was equal to or more than 100Ω and equal to or less than 1000Ω.

A lower limit value of the inductance L of the inductor L1 is set as follows so that an impedance Zcom of the series circuit of the resistor R1 and the inductor L1 during main transfer is larger than an impedance Zcp of the peaking capacitor Cp1 during main transfer.

First, a combined capacitance C of the second transfer capacitor C2 and the peaking capacitor Cp1 is calculated by Expression (1), where a capacitance of the second transfer capacitor C2 is C₂ and a capacitance of the peaking capacitor Cp1 is Cp.

$$C = 1 / ( 1 / {C}_{2} + 1 / Cp ) \qquad ( 1 )$$

A resonance period τ during main transfer is calculated by Expression (2).

$$τ = 2 π \times {( LC )}^{1 / 2} \qquad ( 2 )$$

A resonance angular frequency ω during main transfer is calculated by Expression (3).

$$ω = 2 π / τ \qquad ( 3 )$$

The impedance Zcp of the peaking capacitor Cp1 during main transfer is calculated by Expression (4).

$$Zcp = 1 / ω Cp \qquad ( 4 )$$

The impedance Zcom of the series circuit of the resistor R1 and the inductor L1 during main transfer is calculated by Expression (5).

$$Zcom = {( {( ω L )}^{2} + {R}^{2} )}^{1 / 2} \qquad ( 5 )$$

By setting the lower limit value of the inductance L so as to satisfy the following Expression (6), it is possible to suppress a large pulse current from flowing through the resistor R1 during main transfer.

$$Zcom > Zcp \qquad ( 6 )$$

By using Expression (7) instead of Expression (6), a large pulse current flowing through the resistor R1 during main transfer is further suppressed.

$$Zcom > 10 \times Zcp \qquad ( 7 )$$

On the other hand, since the attenuation effect of the oscillation of the voltage Vcp becomes insufficient when the inductance L of the inductor L1 is too large, an upper limit value of the inductance L is set as follows.

Let Rep be the repetition frequency of the pulse laser light LB, and Tm be a required time for magnetic reset. The required time Tm is the time from a discharge timing indicated by time t1 to a magnetic reset completion timing indicated by time t2 in FIG. 7. By setting the inductance L to satisfy Expression (8), attenuation of the oscillation of the voltage Vcp can be promoted, and the amplitude at the time of the subsequent discharge can be reduced to 20 V or less.

$$L \leq ( 1 / Rep - Tm ) \times R / 2 \qquad ( 8 )$$

By using Expression (9) instead of Expression (8), it is possible to further reduce the amplitude at the time of the subsequent discharge.

$$L \leq ( 1 / Rep - Tm ) \times R / 10 \qquad ( 9 )$$

The inductance L is preferably equal to or more than 0.1 mH and equal to or less than 10.7 mH. The required time Tm for magnetic reset is preferably equal to or more than 40 μs and equal to or less than 80 μs. The resistor R1 may include a plurality of resistance elements. The inductor L1 may include a plurality of inductor elements. Preferably, each of the resistor R1 and the inductor L1 is immersed in insulating oil.

### 3.4 Effect

According to the first embodiment, the pulse power module 13a includes the step-up transformer TC1 in which a pulse current from the main capacitor C0 flows to the primary side, the first magnetic pulse compression circuit PC1, the second magnetic pulse compression circuit PC2, the reset circuit RC, and the series circuit of the resistor R1 and the inductor L1.

The first magnetic pulse compression circuit PC1 includes the first transfer capacitor C1 connected to the secondary side of the step-up transformer TC1 and the magnetic switch SR1 connected to the first transfer capacitor C1, and transfers charge of the first transfer capacitor C1 to the second transfer capacitor C2. The second magnetic pulse compression circuit PC2 includes the second transfer capacitor C2 and the magnetic switch SR2 connected to the second transfer capacitor C2, and transfers charge of the second transfer capacitor C2 to the peaking capacitor Cp1. The reset circuit RC includes the reset windings TR1, LR1, LR2 that reversely excite the cores of the step-up transformer TC1, the magnetic switch SR1, and the magnetic switch SR2 to perform magnetic reset. The series circuit of the resistor R1 and the inductor L1 is connected in parallel to the peaking capacitor Cp1. The resistance value R of the resistor R1 is equal to or more than 100Ω and equal to or less than 1000Ω. When the capacitance of the peaking capacitor Cp1 is Cp, the resonance angular frequency during transfer of charge from the second transfer capacitor C2 to the peaking capacitor Cp1 is ω, the repetition frequency is Rep, and the required time for magnetic reset is Tm, the inductance L of the inductor L1 satisfies the following two expressions.

$${( {( ω L )}^{2} + {R}^{2} )}^{1 / 2} > 1 / ω Cp$$

$$L \leq ( 1 / Rep - Tm ) \times R / 2$$

Accordingly, by setting each of the resistance value R and the inductance L in the series circuit of the resistor R1 and the inductor L1 connected in parallel to the peaking capacitor Cp1 within an appropriate range, it is possible to sufficiently suppress the oscillation of the voltage Vcp after magnetic reset, and to suppress a large pulse current from flowing through the resistor R1 during transfer of the charge from the second transfer capacitor C2 to the peaking capacitor Cp1. By suppressing the oscillation of the voltage Vcp, the pulse energy of the pulse laser light LB can be stabilized. Further, by suppressing the pulse current flowing through the resistor R1, it is possible to suppress loss of charge during transfer.

In other respects, the first embodiment is similar to the comparative example.

### 4. Pulse Laser Device 100b Including Amplifier 120

### 4.1 Configuration

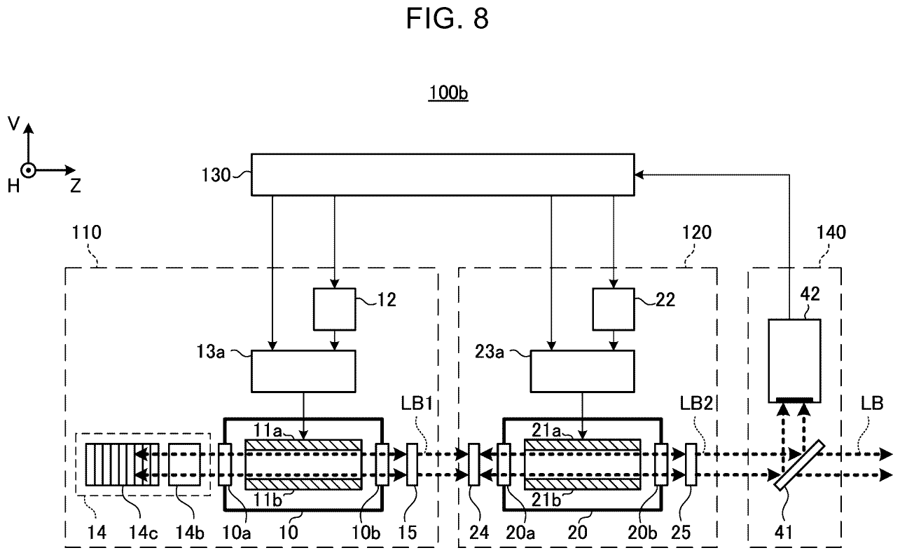

FIG. 8 shows the configuration of a pulse laser device 100b of a second embodiment. The pulse laser device 100b is different from the pulse laser device 100a of the first embodiment in that an amplifier 120 is included between the laser oscillator 110 and the monitor module 140.

The amplifier 120 includes a laser chamber 20, a charger 22, a pulse power module 23a, a rear mirror 24, and an output mirror 25. The rear mirror 24 and the output mirror 25 configure an optical resonator. The rear mirror 24 is configured by a partial reflection mirror having a higher reflectance than the output mirror 25, and is arranged on the optical path of the pulse laser light LB1. The configurations of the laser chamber 20, the charger 22, the pulse power module 23a, and the output mirror 25 are similar to those of the laser chamber 10, the charger 12, the pulse power module 13a, and the output mirror 15, respectively. The pulse power module 23a is an example of the pulse laser power source in the present disclosure. The configurations of windows 20a, 20b and a pair of electrodes 21a, 21b included in the laser chamber 20 are similar to those of the windows 10a, 10b and the electrodes 11a, 11b, respectively.

### 4.2 Operation

The pulse laser light LB1 output from the laser oscillator 110 enters the laser chamber 20 via the rear mirror 24 and the window 20a. The timing at which the oscillation trigger signal is input to the pulse power module 23a is controlled so that discharge is started between the electrodes 21a, 21b at the timing at which the pulse laser light LB1 enters the laser chamber 20. Pulse laser light LB2 output from the output mirror 25 enters the monitor module 140 and enters the exposure apparatus 200 as the pulse laser light LB.

### 4.3 Effect

According to the second embodiment, the laser oscillator 110 and the amplifier 120 include the pulse power module 13a and the pulse power module 23a, respectively, and each of the pulse power modules 13a, 23a includes the series circuit of the resistor R1 and the inductor L1 connected in parallel to the peaking capacitor Cp1, and each of the resistance value R and the inductance L is set into the appropriate range.

Accordingly, a variation in the voltage Vcp during discharge is suppressed in both the laser oscillator 110 and the amplifier 120. Since a variation in the discharge voltage is suppressed, a variation in the pulse energy of the pulse laser light LB2 output from the output mirror 25 is suppressed.

Further, the variation in the voltage Vcp during discharge may cause a deviation in the discharge timing, but by suppressing the variation in the voltage Vcp during discharge, the discharge timing can be accurately controlled. Therefore, it is possible to accurately control the timing at which the pulse laser light LB1 output from the laser oscillator 110 enters the amplifier 120 and the timing at which discharge is started in the amplifier 120.

In other respects, the second embodiment is similar to the first embodiment.

### 5. Others

### 5.1 Processor 130

The processor 130 may be physically configured as hardware to execute various processes included in the present disclosure. For example, the processor 130 may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor 130 may be programmed as software to execute the various processes included in the present disclosure. For example, the processor 130 may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 5.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A pulse laser power source, comprising:
a step-up transformer in which a pulse current from a main capacitor flows to a primary side;
a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor;
a second magnetic pulse compression circuit including the second transfer capacitor and a second magnetic switch connected to the second transfer capacitor, and configured to transfer charge of the second transfer capacitor to a peaking capacitor;
a reset circuit including reset windings that reversely excite cores of the step-up transformer, the first magnetic switch, and the second magnetic switch to perform magnetic reset; and
a series circuit of a resistor and an inductor connected in parallel to the peaking capacitor,
a resistance value of the resistor being equal to or more than 100Ω and equal to or less than 1000Ω, and
an inductance L of the inductor satisfying two expressions of:
$${( {( ω L )}^{2} + {R}^{2} )}^{1 / 2} > 1 / ω Cp , and$$
$$L \leq ( 1 / Rep - Tm ) \times R / 2 ,$$
where a capacitance of the peaking capacitor is Cp, a resonance angular frequency during transfer of charge from the second transfer capacitor to the peaking capacitor is ω, a repetition frequency is Rep, and a required time for the magnetic reset is Tm.

2. The pulse laser power source according to claim 1,
wherein the inductance L satisfies an expression of:
$${( {( ω L )}^{2} + {R}^{2} )}^{1 / 2} > 10 / ω Cp .$$

3. The pulse laser power source according to claim 1, wherein the inductance L satisfies an expression of:
$$L \leq ( 1 / Rep - Tm ) \times R / 10.$$

4. The pulse laser power source according to claim 1, wherein the inductance L satisfies two expressions of:
$${( {( ω L )}^{2} + {R}^{2} )}^{1 / 2} > 10 / ω Cp , and$$
$$L \leq ( 1 / Rep - Tm ) \times R / 10.$$

5. The pulse laser power source according to claim 1,
wherein the required time Tm for the magnetic reset is equal to or more than 40 μs and equal to or less than 80 μs.

6. The pulse laser power source according to claim 1,
wherein the resistor includes a plurality of resistance elements.

7. The pulse laser power source according to claim 1,
wherein the inductor includes a plurality of inductor elements.

8. The pulse laser power source according to claim 1,
wherein the resistor and the inductor are immersed in insulating oil.

9. A pulse laser device comprising:
a step-up transformer in which a pulse current from a main capacitor flows to a primary side;
a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor;
a second magnetic pulse compression circuit including the second transfer capacitor and a second magnetic switch connected to the second transfer capacitor, and configured to transfer charge of the second transfer capacitor to a peaking capacitor;
a reset circuit including reset windings that reversely excite cores of the step-up transformer, the first magnetic switch, and the second magnetic switch to perform magnetic reset;
a series circuit of a resistor and an inductor connected in parallel to the peaking capacitor; and
a laser chamber including a pair of electrodes arranged therein and connected to the peaking capacitor,
a resistance value of the resistor being equal to or more than 100Ω and equal to or less than 1000Ω, and
an inductance L of the inductor satisfying two expressions of:
$${( {( ω L )}^{2} + {R}^{2} )}^{1 / 2} > 1 / ω Cp , and$$
$$L \leq ( 1 / Rep - Tm ) \times R / 2 ,$$
where a capacitance of the peaking capacitor is Cp, a resonance angular frequency during transfer of charge from the second transfer capacitor to the peaking capacitor is ω, a repetition frequency is Rep, and a required time for the magnetic reset is Tm.

10. The pulse laser device according to claim 9,
wherein the inductance L satisfies an expression of:
$${( {( ω L )}^{2} + {R}^{2} )}^{1 / 2} > 10 / ω Cp .$$

11. The pulse laser device according to claim 9,
wherein the inductance L satisfies an expression of:
$$L \leq ( 1 / Rep - Tm ) \times R / 10.$$

12. The pulse laser device according to claim 9, wherein the inductance L satisfies two expressions of:
$${( {( ω L )}^{2} + {R}^{2} )}^{1 / 2} > 10 / ω Cp , and$$
$$L \leq ( 1 / Rep - Tm ) \times R / 10.$$

13. The pulse laser device according to claim 9,
wherein the required time Tm for the magnetic reset is equal to or more than 40 μs and equal to or less than 80 μs.

14. The pulse laser device according to claim 9,
wherein the resistor includes a plurality of resistance elements.

15. The pulse laser device according to claim 9,
wherein the inductor includes a plurality of inductor elements.

16. The pulse laser device according to claim 9,
wherein the resistor and the inductor are immersed in insulating oil.

17. An electronic device manufacturing method, comprising:
generating pulse laser light using a pulse laser device;
outputting the pulse laser light to an exposure apparatus; and
exposing a photosensitive substrate to the pulse laser light in the exposure apparatus to manufacture an electronic device,
the pulse laser device including:
a step-up transformer in which a pulse current from a main capacitor flows to a primary side;
a first magnetic pulse compression circuit including a first transfer capacitor connected to a secondary side of the step-up transformer and a first magnetic switch connected to the first transfer capacitor, and configured to transfer charge of the first transfer capacitor to a second transfer capacitor;
a second magnetic pulse compression circuit including the second transfer capacitor and a second magnetic switch connected to the second transfer capacitor, and configured to transfer charge of the second transfer capacitor to a peaking capacitor;
a reset circuit including reset windings that reversely excite cores of the step-up transformer, the first magnetic switch, and the second magnetic switch to perform magnetic reset;
a series circuit of a resistor and an inductor connected in parallel to the peaking capacitor; and
a laser chamber including a pair of electrodes arranged therein and connected to the peaking capacitor,
a resistance value of the resistor being equal to or more than 100Ω and equal to or less than 1000Ω, and
an inductance L of the inductor satisfying two expressions of:
$${( {( ω L )}^{2} + {R}^{2} )}^{1 / 2} > 1 / ω Cp , and$$
$$L \leq ( 1 / Rep - Tm ) \times R / 2 ,$$
where a capacitance of the peaking capacitor is Cp, a resonance angular frequency during transfer of charge from the second transfer capacitor to the peaking capacitor is ω, a repetition frequency is Rep, and a required time for the magnetic reset is Tm.

18. The electronic device manufacturing method according to claim 17,
wherein the inductance L satisfies an expression of:
$${( {( ω L )}^{2} + {R}^{2} )}^{1 / 2} > 10 / ω Cp .$$

19. The electronic device manufacturing method according to claim 17,
wherein the inductance L satisfies an expression of:
$$L \leq ( 1 / Rep - Tm ) \times R / 10.$$

20. The electronic device manufacturing method according to claim 17,
wherein the inductance L satisfies two expressions of:
$${( {( ω L )}^{2} + {R}^{2} )}^{1 / 2} > 10 / ω Cp , and$$
$$L \leq ( 1 / Rep - Tm ) \times R / 10.$$
